(19) United States
(12) Patent Application Publication
(10) Pub. No.: US 2003/0224263 A1
(43) Pub. Date: Dec. 4, 2003

(54) Process for producing precision metal components

(76) Inventor: Toshiharu Matsuoka, Saitma-ken (JP)

Correspondence Address: George W. Rauchfuss, Jr., Ohlandt, Greeley, Ruggiero & Perle, L.L.P., One Landmark Square, Tenth Floor, Stamford, CT, 06901-2682, US

(21) Appl. No.: 10/390,962

(22) Filed: Mar. 18, 2003

(30) Foreign Application Priority Data
Mar. 18, 2002 (JP) 2002-075243

(51) Int. Cl. G03F 9/00; G03F 7/16; G03F 7/20; G03F 7/40; C25D 1/00

(52) U.S. Cl. 430/22; 430/394; 430/321; 430/323; 205/79

(57) ABSTRACT

A process for producing a precision component is provided. In one embodiment of the process comprising adhering a resist on a surface of a metal material, forming resist coated parts and metal exposed parts by exposure to light and developing, and etching the metal exposed parts alone to form perforated parts or indented parts, the process is characterized in that a) at least a thin copper layer is included as a surface on which a resist is adhered, b) at least a nickel layer which is in contact with said copper layer is included, c) precision parts made by removing precise amount of metal are formed from said nickel layer, and d) the thickness of said thin copper layer is sufficiently thin to be made disappeared at the exposed metal surface parts by a nickel etching solution when said nickel layer is etched.

### FIELD OF THE INVENTION

The present invention relates to a process for producing precision metal components or parts, particularly those for an optical encoder having slits, etc.

### BACKGROUND OF THE INVENTION

Prior Art

Japanese Examined Patent Publication No. H01-46592 discloses that a plate with precise optical slits (such as those for encoders) may be obtained by preventing deterioration of precision due to etching, by a process in which the width of the slits of a precision metal part is wider at the second and the third metal layers than at the first metal layer in the cross-section.

In the embodiment of the above-mentioned publication, nickel is used in the first and the third layers (surface layers) and copper is used in the second layer (intermediate layer). A commercially available resist is applied on the nickel layer, on which a film is applied and developed, and then sequentially etched with an acidic etching solution and an alkaline etching solution to etch the nickel layer and then the copper layer to make perforations (see Example 1 of the publication).

The reason to use nickel metal on the surface layer in the invention of the publication is that precision cannot be obtained if copper layers are on the surfaces because copper layer is etched to some extent when the nickel intermediate layer is etched with the acidic etching solution.

However, there are drawbacks in the above-mentioned process as described below. Firstly, it is generally difficult to say that a resist is always successfully adhered to a nickel layer. If a resist does not adhere successfully to the metal surface, increased rejects make commercial production unpractical. On the other hand, when slits are formed in a plate consisting of plurality of metal layers, of which the surface layer is copper and the intermediate layer is nickel as in the case of three layers of copper/nickel/copper described above, one will not find it very successful because the surface copper layer on which the precision depends is subjected to etching when the intermediate nickel layer is etched.

Secondly, nickel surface is liable to be scratched. A plate form precision metal part needs to have a flat surface which is free from scratches. If the nickel layer on which precision depends has scratches just on a precision-requiring perforated part such as a slit, even a shallow one can increase probability of causing a reject with regard to the precision of slits. Thus, it is preferred that the nickel layer by which slit precision is provided is protected so that the surface is not scratched during handling of the plate and steps of a severe condition before slits are formed. Particularly, when a three-layered thin metal plate is produced by means of plating using a roll, the formed plate, after stripped from the roll, must be annealed until flat since it is made in a curved state along the roll. When the surface is a nickel layer, sometimes the plate surface cannot be made flat completely due to that annealing step. Furthermore, nickel can be oxidized and discolored by heat since baking is involved in annealing.

Furthermore, since selective patterning by etching or plating is carried out not only in precision parts having perforations such as the above-mentioned light passing type encoders, but also on precision parts having different metal surfaces so that reflective and non-reflective surfaces are formed as in the case of light reflecting type encoders, problem arises when a commonly used resist is adhered to a material other than copper.

### OBJECT OF THE INVENTION

Research efforts have been made by the applicant to solve the above-mentioned problems, and the applicant attained the present invention with the constitutional elements described below, after the discoveries:

that good resist adherence results may be obtained when very thin copper layer is formed on the surface for the purpose of improving adherence of resist, that the thin copper layer may be regarded as if it is a part of the nickel layer with regard to etching of the surfaces not covered by the resist,

that nickel layer by which precision is provided at precise parts may be protected from scratches, oxidation and discoloration even before the resist is adhered, and

that, in the case when the plate surfaces having very thin copper layers are selectively covered by a resist and the parts of the surfaces not covered by the resist are plated to reflect light with a metal other than copper such as nickel, there is a synergistic effect in the use of the very thin copper layer on the non-copper substrate for the purpose of improving adherence of resist because even the very thin copper layers can form a metal oxide film as non-light reflecting surfaces.

### SUMMARY OF THE INVENTION

Namely, the present invention which can be applied in various types of invention comprises the constitutional elements described below.

1. In a process for producing a precision metal component comprising the steps of adhering a resist on the surface of a metal material having a plurality of layers, exposing the surface to light in a predetermined pattern using photographic technique to remove light-unexposed parts of the resist to form exposed metal surface parts on which there is no resist, and etching the exposed metal surface parts to form either indentations indenting at least from the contacting surface between said resist and said metal material or perforations perforated from said contacting surface to the other surface in said metal material, the method characterized in that:

a) at least a thin copper layer is included in said plurality of layers as a surface on which a resist is adhered,

b) at least a nickel layer which is in contact with said thin copper layer is included in said plurality of layers,

c) precision parts made by removing precise amount of metal are formed from said nickel layer, and

d) the thickness of said thin copper layer is sufficiently thin to be made disappeared at the exposed metal surface parts by a nickel etching solution when said nickel layer is etched.

2. A process according to 1 above wherein said nickel layer is in contact with another copper layer, and wherein the step of forming indentations indenting from the contacting surface between said resist and said metal material into said metal material is carried out by removing said nickel layer at the exposed metal surface parts during said nickel layer etching until said another copper layer is exposed. In this case, for example, if the thin copper layer is removed by abrasion and a black colored oxide layer is formed on said another copper layer, a precision metal component for a reflecting type encoder having reflecting surfaces of nickel layer and non-reflecting surfaces of black oxide layer may be produced as an improvement of the invention described in Japanese Patent Publication 2000-283794.

Following 3 to 5 is an improvement of the invention described in Japanese Examined Patent Publication H01-46592.

3. A process for producing a precision metal component with perforated parts comprising the steps of

providing a metal plate having a plurality of layers in the order of copper, nickel, copper, nickel and copper in cross-section from one surface to the other (e.g., from top surface to bottom surface or from front surface to back surface), said copper layers on both the surfaces being much thinner than other layers,

adhering a resist on both the surfaces of said metal plate,

placing a glass or film patterned masks on both the surfaces and exposing it to light, said patterned masks having respective generally symmetrically corresponding patterns and being aligned with each other,

removing parts of the resist corresponding to said patterns to make both the surfaces of said metal plate to have metal exposed parts,

etching, at said metal exposed parts, said thin copper layers on the surfaces and said nickel layers below them with a first etching solution,

etching said copper layer which has been exposed below said nickel layer etched in the previous step with a second etching solution to form perforated parts in said metal plate having a plurality of layers, and

removing remaining resist.

4. A process according to 3 above wherein said glass or film masks having generally symmetrically corresponding mask patterns to be placed on both the surfaces of said metal plate with resist have respective mask patterns which are slightly different in size such that the widths of the metal exposed parts on one surface is made wider than the corresponding metal exposed parts on the other surface.

5. A process according to 3 above wherein said glass or film masks having generally symmetrically corresponding mask patterns to be placed on both the surfaces of said metal plate with resist have the respective mask patterns which are slightly different in size such that the widths of the metal exposed parts on one surface is made wider than the corresponding metal exposed parts on the other surface, and wherein the nickel layer near the surface having narrower width of the metal exposed parts has a thickness thinner than those of said intermediate copper layer and the other nickel layer.

6. In a process of producing a precision metal component comprising the steps of

adhering a resist on the surface of a material in a predetermined precision pattern using photographic technique,

either plating the material with a metal so that the metal is added on the exposed parts of the material or etching the material so that a metal is removed from the material, and

removing the resist,

the method characterized in that said material has, on a non-copper material, at least a thin copper layer as a surface on which the resist is adhered.

7. In a process of producing a precision metal component having a metal surface of a predetermined pattern, comprising the steps of

adhering a resist on the surface of a material in a predetermined precision pattern by exposing the surface to light in the predetermined pattern using photographic technique to remove light-unexposed parts of the resist to form exposed surface parts on which there is no resist,

plating the material with a metal so that the metal is added on the exposed parts of the material to form metal-plated parts on said material, and

removing the resist,

the process being characterized in that said material has, on a non-copper material, at least a thin copper layer as a surface on which the resist is adhered, and further characterized in that said material has at least a copper layer as a surface on which the resist is adhered, said copper layer being in intimate contact with a plate of glass/epoxy or alumina/epoxy composite material, and that said metal for plating on said copper layer is other than copper.

8. A process of 7 above further comprising the step of completely removing the exposed parts of said copper layer after said removal of the resist.

9. A process of 7 above further comprising the step of forming an oxide film which does not reflect light well on the exposed parts of said copper layer after said removal of the resist.

### BRIEF DESCRIPTION OF THE DRAWINGS

FIG. 1 illustrates process steps of one embodiment of the invention for producing metal components having perforated parts, in which the component produced in each step is shown in cross-section.

FIG. 2 illustrates process steps of one embodiment of the invention for producing metal components having indentations, in which the component produced in each step is shown in cross-section.

FIG. 3 is an illustration of process steps to produce a metal plate having plurality of layers.

FIG. 4 is an illustration of process steps to produce a metal plate having plurality of layers.

FIG. 5 is an illustration of process steps to produce a metal plate having plurality of layers.

FIG. 6 illustrates process steps for producing a precision metal component for a reflecting type encoder using a material of glass-epoxy plate on which copper foil is layered or plated, in which the component produced in each step is shown in cross-section.

### DETAILED DESCRIPTION OF THE INVENTION

Explanations to Terms

Very Thin Copper Layer

The thickness of the “very thin copper layer” or “thin copper layer” may be one which allow removal of the copper layer by, for example, etching of nickel layer when there is a nickel layer under the thin copper layer. For example, when the total thickness of the plate is about 100μ, it can be said that the copper layer having a thickness of 5μ or smaller is readily removed. Also, similar thickness may be used when the thin copper layer is converted to a non-reflecting surface by the formation of oxide layer. So long as there is a copper layer, effective surface copper layer may be as thin as possible.

Resist

In the present invention, any commercially available resists having good adhesion to copper may be used.

Nickel Etching Solution or the First Etching Solution

Well known acidic nickel etching solution may be used. For example, an aqueous solution of 10% and 20% of nitric acid and hydrogen peroxide, respectively, as described in Example 1 of Japanese Examined Patent Publication No. H01-46592 may be used.

Copper Etching Solution or the Second Etching Solution

An alkaline etching solution is usually used.

Examples of Indentations at Least Indenting and Perforations Perforated to the Other Surface

In the case of components for optical reflecting type encoders, when indentations indenting from the surface of the surroundings are formed by removal of metal and another metal layer is exposed thereby, the indented part can have a different reflecting property from the surface of the surroundings. Particularly when the indented parts exposes a copper layer, an oxide layer may be formed in the indentations to make them non-reflecting. It is known that a non-reflecting black colored oxide layer can be formed on the surface of copper using a commercially available reagent. It can be possible that a different metal is embedded in the indentations. See Japanese Unexamined Patent Publication No. 2000-283794 for more details. There are cases where precise indented parts are provided on a shaft of a motor etc. utilizing a fluid-dynamic baring, in addition to optical reflecting type encoders. Perforations can generate signals by alternately allowing and blocking passage of light to a sensor of a light-receptor part when such perforated parts are provided, for example, in a rotating component of a light passing type encoder.

Metal Material with Plurality of Layers/Metal Plate with Plurality of Layers/Nickel Plating/Copper Plating

Metal material with plurality of layers and metal plate with plurality of layers, etc. used in the present invention may be produced by any method. Convenient methods due to low cost are as follows. Roll plating method in which a stainless roll is dipped in a plating bath, layers of metals are formed, and the formed metal plate is stripped from the roll and annealed to make the plate flat. Vertical plating method in which an existing thin copper plate in a vertically dipped state is electroplated in a plating bath of nickel, and then copper. Or vertical plating method in which a stainless steel plate is dipped in a plating bath in a vertical position, electroplating is carried out on both the surfaces in the order of copper, nickel, copper, nickel and copper, and then the formed metal layers are stripped from both the surface of the stainless plate.

Nickel plating solution includes sulfamic acid nickel bath, and copper plating solution includes copper sulfate bath. It may also be possible to form metal layers by any known method in addition to electroplating.

Resists/Exposure to Light/Formation of an Image Pattern

Well known photographic or photoengraving process and commercially available well known etching solution may be used. Before resist is adhered, the copper surface may be defatted, washed with water, or dried if necessary.

With regard to attainment of good precision of slits of an encoder by applying film or glass masks having symmetrical slit patterns respectively to both the front and rear surfaces with the width of slits on the precision attaining side being narrower, as well as allowance of slight deviation from alignment of the patterns of the masks are as described also in Japanese Examined Patent Publication No. H01-046592.

### EXAMPLES

The present invention will be explained by reference to drawings.

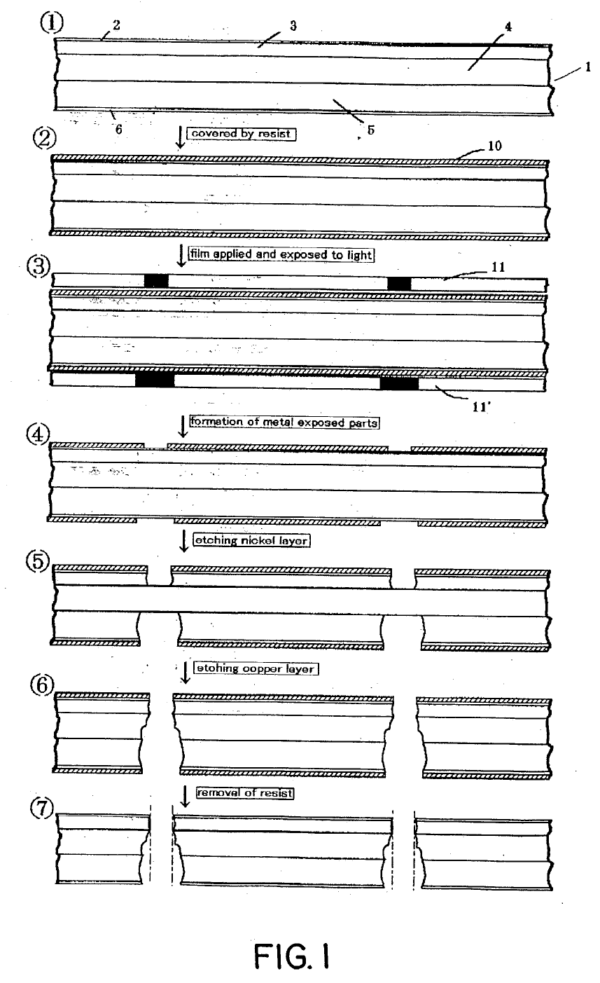

FIG. 1 illustrates process steps for producing precision metal components having perforated parts of precise dimensions (such as slits) of the present invention. The component produced in each step is shown in cross-section.

Firstly, resist 10 is adhered to the layered metal plate 1 of step (1) to make the state shown in step (2). In this case, surface copper layers 2 and 6 allow resist 10 to adhere to the layered metal plate 1 firmly.

Films 11, 11′ having transparent and opaque parts in a predetermined pattern are applied to the front and back surfaces of plate 1 as shown in step (3), and exposure to light is conducted. In this case, just as described in Japanese Examined Patent Publication No. H01-046592, the patterns of film 11 and film 11′ are aligned and symmetrically corresponding each other, but on the side on which precision is attained, pattern is made narrower so that smaller (narrower) light-unexposed parts are encompassed by corresponding light-unexposed parts of the other surface. Then since film 11 can be deviated from film 11′ within an allowable range, slits may be readily formed with excellent precision.

After exposure to light, light-unexposed resist parts are removed, and the state shown by (4) with selective-resist-removed metal-exposed parts is attained.

Then, nickel layers 3 and 5 are etched. Although copper layers 2 and 6 are on the surface at the metal exposing parts in the state shown by (4), these layers are removed by an acidic nickel etching solution (e.g. by splaying an aqueous solution having nitric acid and hydrogen peroxide at 10% and 20%, respectively for 3 minutes as described in Example 1 of Japanese Examined Patent Publication No. H010-46592) because they are thin. On this account, the state (5) may be attained.

Copper layer 4 is then etched. When copper layer 4 is subjected to etching with a commonly used commercially available alkaline etching solution which does not etch nickel layer, the state of (6) is attained. Etching proceeds in copper layers 2 and 6 if exposed.

The resist is then removed with a commercial stripping agent or acetone to result in a product shown as (7).

In FIG. 1, deterioration of precision of slits influenced by side etch (lateral curve of the cross-section of the etched part of metal) during etching is made unrelated to the thickness of copper layer 4 or nickel layer 5, and the precision is attained by making the width of the perforated parts (slits) narrowest at nickel layer 3 (which may be relatively thinner layer). Since role of copper layer 2 is mainly to help resist to adhere and to protect nickel layers in the course of production process, it may be diminished near the slits in the final product.

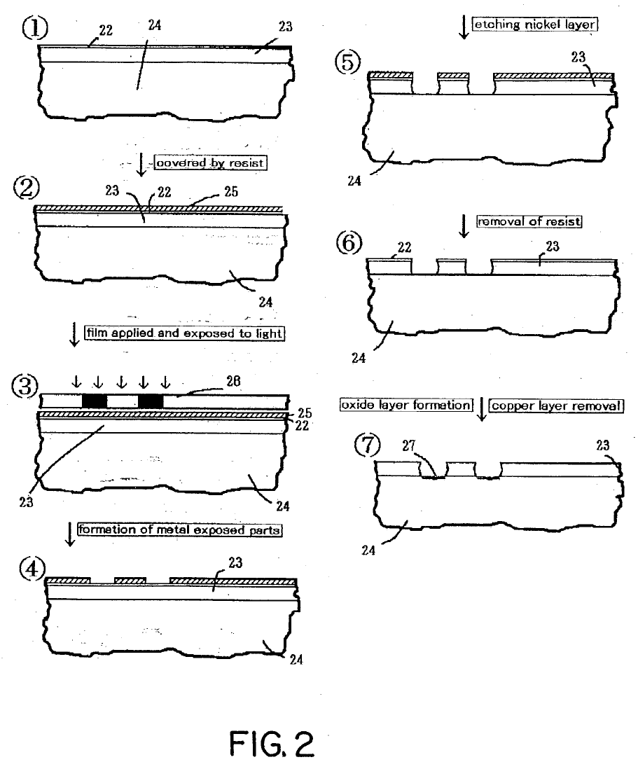

FIG. 2 illustrates process steps for producing precision metal components with reflecting and non reflecting surfaces of precise widths for use in a reflecting type optical encoder, in which the component produced in each step is shown in cross section. Steps (1) to (5) are the same with those shown in FIG. 1 except that only one surface is treated instead of both the surfaces. The resist is removed in step (6) without etching copper, oxide layer 27 is formed in step (7), and surface copper is removed by an appropriate method (such as by abrasion). Then the nickel surface gives reflecting surfaces and the oxide surface on the copper surface in the indented parts gives non-reflecting surfaces.

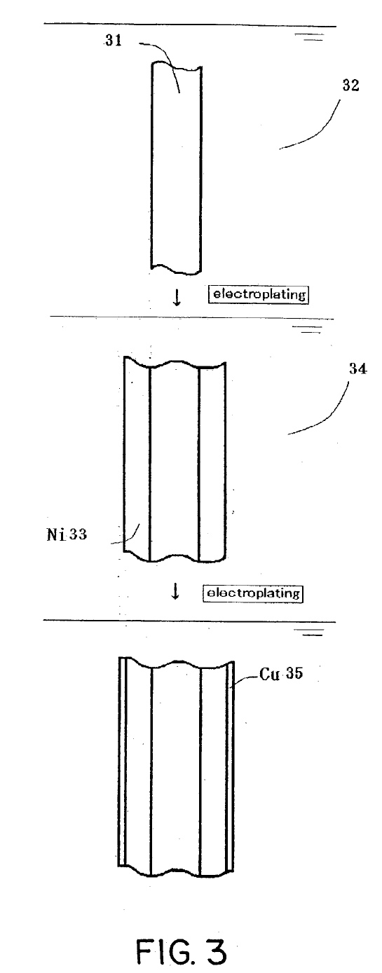

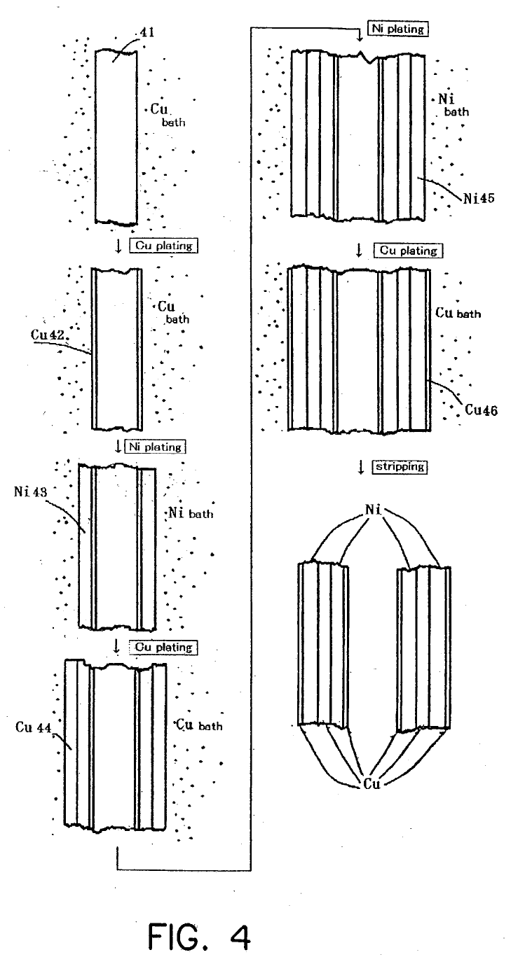

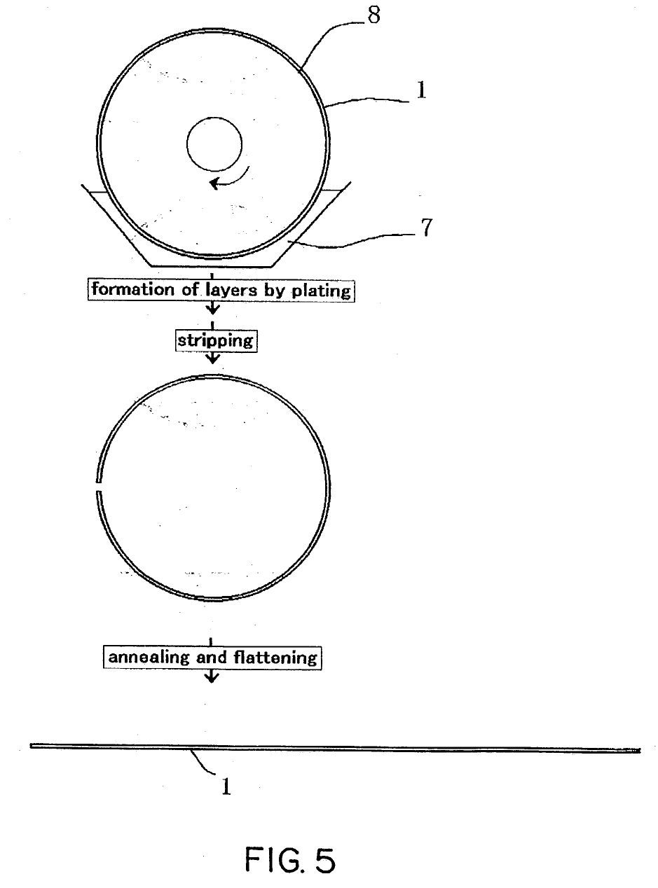

FIG. 3, FIG. 4 and FIG. 5 are illustrations to show the examples of processes of making a (layered) metal plate having plurality of layers used in the process of the present invention.

Each of the layers of the layered metal plate shown at the end of FIGS. 3 to 5, or each of copper layer 2, nickel layer 3, copper layer 4, nickel layer 5, and copper layer 6 in layered plate 1 as shown in FIG. 1, step (1) may be produced by plating method, such as one shown in FIGS. 3 to 5. In FIG. 5, the respective layers are sequentially formed on a stainless roll 8 which is dipped in plating bath 7 which is correspondingly changed according to the respective metals (sulfamic acid nickel bath or copper sulfate bath). After all the metal layers in the order of copper, nickel, copper, nickel and copper have been formed by plating on the stainless roll, the multi-layered plate 1 in the curved state is stripped from the stainless roll 8 and subjected to annealing and flattening process to obtain a flat multi-layered metal plate 1. During the annealing and flattening process, presence of increased number of layers and presence of more malleable copper layer on the surface makes flattening process somewhat smoother. In the processes in FIG. 3 and FIG. 4, annealing is not necessary because the metal plate is subjected to plating in flat state.

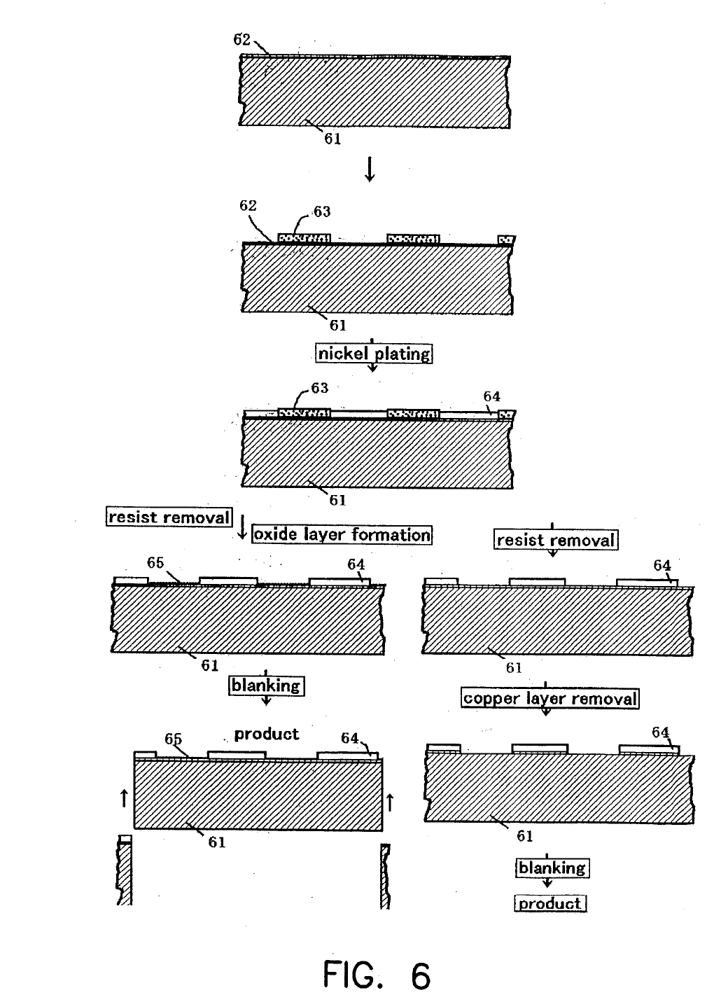

FIG. 6 shows process steps for producing a component having precise reflecting surfaces and non-reflecting surfaces or having transparent (light passing) parts and opaque (non light passing) parts (if the multi-layered composite material is transparent), using a multi-layered composite material such as glass-epoxy plate etc. instead of copper and nickel layers of the precision metal component shown in FIG. 2. When a precision metal component made of a thin plate is reinforced by increasing the thickness, thickness of the metal itself is usually increased. When the metal plate is thicker, narrow patterns, e.g. narrow slits cannot be formed due to etching. If a transparent composite materials such as glass/epoxy material or alumina/epoxy material used for print board etc. are used instead of metal, physical strength and thickness can be secured. By providing an extremely thin layer of copper on a glass/epoxy board, production of such a precision component becomes possible. In the process of FIG. 6, an extremely thin copper layer 62 is adhered to the surface of glass/epoxy 61 by any appropriate means. Then a resist is adhered on the copper layer 62 and a film or glass mask having a desired pattern image is applied and exposed to light. Then the resist 63 is made to remain only in the predetermined precise pattern. On the parts where the material is not covered by the resist but is exposed are plated with nickel to form nickel part 64. Then resist is removed. When it is intended to obtain a component with reflecting and non reflecting surfaces on the treated surface, a copper oxide layer 65 is formed on the exposed surface parts of the extremely thin copper layer. On the other hand, when it is intended to obtain a component with light-passing and non light-passing parts by the treatment of the surface, the exposed extremely thin copper layer is removed by, for example, etching. In any case, the major thickness is provided by the glass/epoxy 61 and the metal layer is thin. Accordingly, this process is convenient to produce many components at a time such as by blanking without distortion or other influences to the product parts, after the surface of one relatively large sized board is treated.

Effectiveness of the Invention

By providing at least a thin copper layer for adhering a resist, the resist can be adhere well to the surface, and generation of rejects can be prevented.

Since the nickel layer from which the metal is selectively removed to result in precise dimension and shape is protected by a copper layer during any severe treatment steps such as baking etc. when annealed before the removal (etching) step, probability of causing scratches, oxidation and discoloration in or on the nickel layer by which precision is provided is made smaller, and generation of rejects is decreased.

When the multi-layered metal plate is produced by plating using a roll, flattening process is needed. The thin surface copper layer helps to alleviate distortions caused by flattening.

In an invention of a process for producing a precision metal component from a multi-layered plate of nickel, copper and nickel layers, deterioration of precision due to side etch (lateral curve of removed metal) is made smaller in the case where resist is adhered to both the surfaces and etching is carried out from both the surfaces than in the case where etching is carried out from one surface, as described in the above-mentioned patent. The same effect is naturally obtained when a precision metal component is produced from a multi-layered plate having copper, nickel, copper, nickel, and copper layers.

When a thin copper layer is adhered on a transparent non-metal composite material, the thin copper layer improves adhesion of the resist, and hence photographic or photoengraving technique may be successfully applied to the composite material. To make a light-passing type precision component, perforation all the way though the material by etching is not necessary. Thus, it is made possible to produce a precision component without restraint, e.g. of slit width, by its thickness. Also, even for the production of light reflecting type precision components, strength and thickness can be readily obtained and yet processing such as blanking etc. is possible. Thus, there is advantages in the production.

1. In a process for producing a precision metal component comprising the steps of adhering a resist on the surface of a metal material having a plurality of layers, exposing the surface to light in a predetermined pattern using photographic technique to remove light-unexposed parts of the resist to form exposed metal surface parts on which there is no resist, and etching the exposed metal surface parts to form either indentations indenting at least from the contacting surface between said resist and said material or perforations perforated from said contacting surface to the other surface in said metal material, the method characterized in that
a) at least a thin copper layer is included in said plurality of layers as a surface on which the resist is adhered,
b) at least a nickel layer which is in contact with said copper layer is included in said plurality of layers,
c) precision parts made by removing precise sizes of metal are formed from said nickel layer, and
d) the thickness of said thin copper layer is sufficiently thin to be made disappeared at the exposed metal surface parts by a nickel etching solution when said nickel layer is etched.

2. A process according to claim 1 wherein said nickel layer is in contact with another copper layer, and wherein the step of forming indentations indenting from the contacting surface between said resist and said metal material into said metal material is carried out by removing said nickel layer at the exposed metal surface parts during said nickel layer etching until said another copper layer is exposed.

3. A process for producing a precision metal component with perforated parts comprising the steps of
providing a metal plate having a plurality of layers in the order of copper, nickel, copper, nickel and copper in cross-section from one surface to the other, said copper layers on both the surfaces being much thinner than other layers, adhering a resist on both the surfaces of said metal plate,
placing a glass or film patterned masks on both the surfaces and exposing it to light, said patterned masks having respective generally symmetrically corresponding patterns and being aligned each other,
removing parts of the resist corresponding to said patterns to make both the surfaces of said metal plate to have metal exposed parts,
etching, at said metal exposed parts, said thin copper layers on the surfaces and said nickel layers below them with a first etching solution,
etching said copper layer which has been exposed below said nickel layer etched in the previous step with a second etching solution to form perforated parts in said metal plate having a plurality of layers, and
removing the remaining resist.

4. A process according to claim 3 wherein said glass or film masks having generally symmetrically corresponding mask patterns to be placed on both the surfaces of said metal plate with resist have the respective mask patterns which are slightly different in size such that the widths of the metal exposed parts on one surface is made wider than the corresponding metal exposed parts on the other surface.

5. A process according to claim 3 wherein said glass or film masks having generally symmetrically corresponding mask patterns to be placed on both the surfaces of said metal plate with resist have the respective mask patterns which are slightly different in size such that the widths of the metal exposed parts on one surface is made wider than the corresponding metal exposed parts on the other surface, and wherein the nickel layer near the surface having narrower width of the metal exposed parts has a thickness thinner than those of said intermediate copper layer and the other nickel layer.

6. In a process of producing a precision metal component comprising the steps of
adhering a resist on the surface of a material in a predetermined precision pattern using photographic technique,
either plating the material with a metal so that the metal is added on the exposed parts of the material or etching the material so that a metal is removed from the material, and
removing the resist,
the method characterized in that said material has, on a non-copper material, at least a thin copper layer as a surface on which the resist is adhered.

7. In a process of producing a precision metal component having a metal surface of a predetermined pattern, comprising the steps of
adhering a resist on the surface of a material in a predetermined precision pattern by exposing the surface to light in the predetermined pattern using photographic technique to remove light-unexposed parts of the resist to form exposed surface parts on which there is no resist,
plating the material with a metal so that the metal is added on the exposed parts of the material to form metal-plated parts on said material, and
removing the resist,
the process being characterized in that said material has, on a non-copper material, at least a thin copper layer as a surface on which the resist is adhered, and further characterized in that said material has at least a copper layer as a surface on which the resist is adhered, said copper layer being in intimate contact with a plate of glass/epoxy or alumina/epoxy composite material, and that said metal for plating on said copper layer is other than copper.

8. A process of claim 7 further comprising the step of completely removing the exposed parts of said copper layer after said removal of the resist.

9. A process of claim 7 further comprising the step of forming an oxide film which do not reflect light well on the exposed parts of said copper layer after said removal of the resist.
